(19) United States
(12) Patent Application Publication
(10) Pub. No.: US 2024/0134423 A1
(43) Pub. Date: Apr. 25, 2024

(54) EXPANDABLE GRAPHICS PROCESSING UNIT BRACKET ASSEMBLY

(71) Applicant: LINKUP Technology Incorporated, Richmond Hill (CA)

(72) Inventor: Patrick S. East, Toronto (CA)

(73) Assignee: LINKUP Technology Incorporated, Richmond Hill (CA)

(21) Appl. No.: 18/401,618

(22) Filed: Dec. 31, 2023

Related U.S. Application Data
(63) Continuation of application No. 29/781,367, filed on Apr. 29, 2021.

(51) Int. Cl. G06F 1/18; H05K 7/14

(52) U.S. Cl. CPC G06F 1/183; H05K 7/1461

(57) ABSTRACT

The present invention is an expandable graphics processing unit bracket assembly for retaining, securing and/or positioning a graphics processing unit, preferably in a vertical position. The expandable bracket assembly is adjustable along at least one axis, preferably multiple axes, so as to be able to provide a plurality of alternative or customized orientations and configurations to fit within or work with different computer cases and housings and related devices and systems, to accommodate graphics processing units of different shapes and sizes, and to offer more support for heavier graphics processing units. The expandable bracket assembly increases compatibility with different computer case designs, graphics processing units, connecting devices, and related devices and systems by having certain components and parts that can be adjusted to different alternative positions along multiple axes to match the characteristics of the different computer case designs, graphics processing units, and related devices and systems.

### CROSS-REFERENCE TO RELATED APPLICATIONS

The present application claims the priority benefit of U.S. Design patent application Ser. No. 29/781,367, filed on Apr. 29, 2021 and titled “COMPUTER CASE,” which is incorporated herein by reference in its entirety.

### BACKGROUND OF THE INVENTION

### Field of the Invention

The present invention generally relates to computer cases, computer case brackets, and graphics processing unit brackets. More specifically, the present invention is an expandable graphics processing unit bracket assembly for retaining, securing and/or positioning a graphics processing unit, preferably in a vertical position.

### Description of the Related Art

Computer cases, computer case brackets, and graphics processing unit brackets are known in the art.

The present invention overcomes one or more of the shortcomings of known computer cases, computer case brackets, and graphics processing unit brackets. The Applicant is unaware of inventions or patent documents, taken either singly or in combination, which are seen to describe the present invention as claimed.

An advantage of the present invention is that it is adjustable along multiple axes so as to be able to provide a plurality of alternative or customized orientations and configurations to fit within or work with different computer cases and housings.

Another advantage of the present invention is that it is adjustable along multiple axes so as to be able to accommodate graphics processing units of different shapes and sizes.

A further advantage of the present invention is that it is adjustable along multiple axes so as to be able to offer more support for heavier graphics processing units.

### SUMMARY OF THE PRESENT INVENTION

The present invention is an expandable graphics processing unit bracket assembly (also referred to as expandable bracket assembly) for retaining, securing and/or positioning a graphics processing unit, preferably in a vertical position. The expandable bracket assembly is adjustable along at least one axis, preferably multiple axes, so as to be able to provide a plurality of alternative or customized orientations and configurations to fit within or work with different computer cases and housings and related devices and systems, to accommodate graphics processing units of different shapes and sizes, and to offer more support for heavier graphics processing units.

The expandable bracket assembly increases compatibility with different computer case designs, graphics processing units, connecting devices, and related devices and systems by having certain components and parts that can be adjusted to different alternative positions along multiple axes (a front-to-rear axis, a side-to-side axis, and a top-to-bottom axis) to match the characteristics (such as, but not limited to, shape, size, weight, etc.) of the different computer case designs, graphics processing units, and related devices and systems.

As a non-limiting embodiment, the expandable bracket assembly preferably comprises most or all of a front panel, a bracket, a bracket extension, a GPU support member, at least one front panel-bracket securing element, at least one bracket-bracket extension securing element, at least one bracket extension-GPU support member securing element, and at least one GPU support member securing element.

### BRIEF DESCRIPTION OF THE DRAWINGS

FIG. 1 is an exploded, perspective, front, left side view of an expandable graphics processing unit bracket assembly according to the present invention;

FIG. 2 is a front view of the expandable graphics processing unit bracket assembly of FIG. 1;

FIG. 3 is a rear view of the expandable graphics processing unit bracket assembly of FIG. 1;

FIG. 4 is a left side view of the expandable graphics processing unit bracket assembly of FIG. 1;

FIG. 5 is a right side view of the expandable graphics processing unit bracket assembly of FIG. 1;

FIG. 6 is a top view of the expandable graphics processing unit bracket assembly of FIG. 1;

FIG. 7 is a bottom view of the expandable graphics processing unit bracket assembly of FIG. 1;

FIG. 8A is a perspective, front, left side view of the expandable graphics processing unit bracket assembly of FIG. 1, wherein the bracket assembly is in a first position along a front-to-rear axis;

FIG. 8B is a perspective, front, left side view of the expandable graphics processing unit bracket assembly of FIG. 1, wherein the bracket assembly is in a second or another position along the front-to-rear axis;

FIG. 9A is a perspective, front, left side view of the expandable graphics processing unit bracket assembly of FIG. 1, wherein the bracket assembly is in a first position along a side-to-side axis;

FIG. 9B is a perspective, front, left side view of the expandable graphics processing unit bracket assembly of FIG. 1, wherein the bracket assembly is in a second or another position along the side-to-side axis;

FIG. 10A is a perspective, front, left side view of the expandable graphics processing unit bracket assembly of FIG. 1, wherein the bracket assembly is in a first position along a top-to-bottom axis;

FIG. 10B is a perspective, front, left side view of the expandable graphics processing unit bracket assembly of FIG. 1, wherein the bracket assembly is in a second or another position along the top-to-bottom axis;

FIG. 11 is an environmental, left side view of the expandable graphics processing unit bracket assembly of FIG. 1, wherein a graphics processing unit is retained by the bracket assembly;

FIG. 12 is an environmental, perspective, left side view of the expandable graphics processing unit bracket assembly of FIG. 1, wherein the bracket assembly is secured within a computer case;

FIG. 13 is an environmental, perspective, left side view of the expandable graphics processing unit bracket assembly of FIG. 1, wherein a graphics processing unit is retained by the bracket assembly and secured within a computer case;

FIG. 14 is an environmental, perspective, front, left side view of the expandable graphics processing unit bracket assembly of FIG. 1, wherein, in a first configuration, a graphics processing unit is retained by the bracket assembly and secured within a computer case;

FIG. 15 is an environmental, perspective, front, left side view of the expandable graphics processing unit bracket assembly of FIG. 1, wherein, in a second configuration, a graphics processing unit is retained by the bracket assembly and secured within a computer case; and

FIG. 16 is an environmental, perspective, front, left side view of the expandable graphics processing unit bracket assembly of FIG. 1, wherein, in a third configuration, a graphics processing unit is retained by the bracket assembly and secured within a computer case.

It should be understood that the above-attached figures are not intended to limit the scope of the present invention in any way.

### DETAILED DESCRIPTION OF THE EMBODIMENTS OF THE PRESENT INVENTION

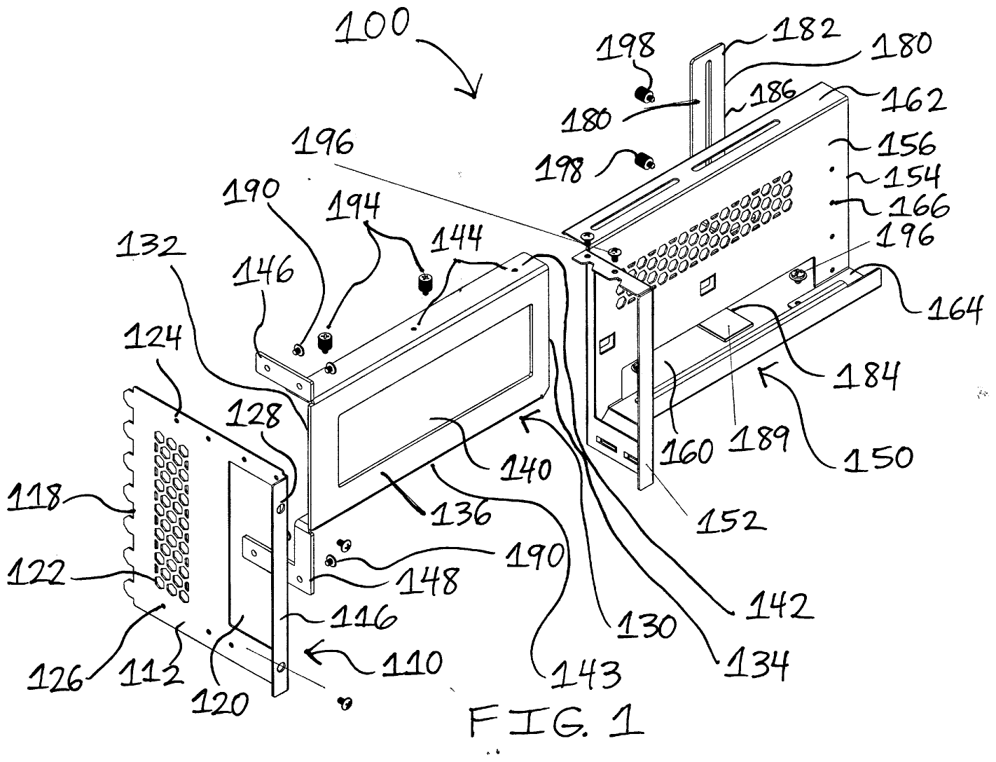

With regard to FIGS. 1-16, the present invention is an expandable graphics processing unit bracket assembly 100 (also referred to as expandable bracket assembly) for retaining, securing and/or positioning a graphics processing unit GPU, preferably in a vertical position. As a non-limiting example, the expandable bracket assembly 100 retains, secures and/or positions a graphics processing unit GPU in a vertical position, preferably, within a computer case or housing CASE such that, for example, personal computer (PC) builders and PC gamers can show off their fancy and/or expensive graphics processing units GPUs in their “custom” computer systems. As a non-limiting example, the graphics processing unit GPU may be connected to a mainboard remotely using a riser cable.

The expandable bracket assembly 100 is adjustable along at least one axis, preferably multiple axes, so as to be able to provide a plurality of alternative or customized orientations and configurations to fit within or work with different computer cases and housings CASE and related devices and systems, to accommodate graphics processing units GPUs of different shapes and sizes, and to offer more support for heavier graphics processing units GPUs.

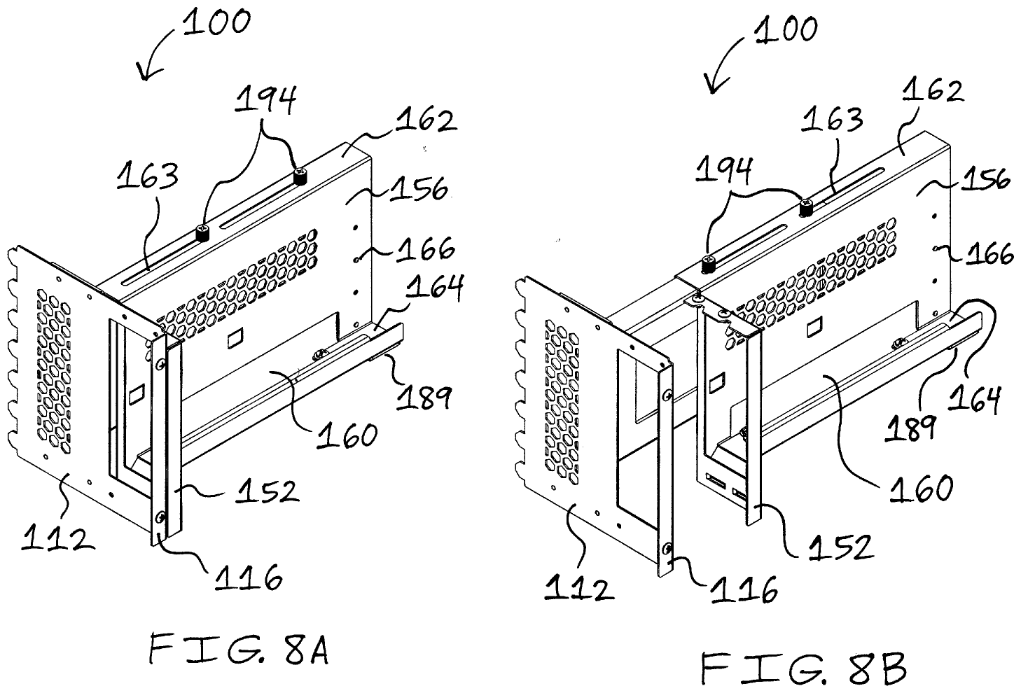

As best shown in FIGS. 8A-8B, 9A-9B, and 10A-10B, the expandable bracket assembly 100 increases compatibility with different computer case designs CASE, graphics processing units GPUs, connecting devices, and related devices and systems by having certain components and parts that can be adjusted to different alternative positions along at least one axis, preferably multiple axes of a front-to-rear axis, a side-to-side axis, and a top-to-bottom axis), to match the characteristics (such as, but not limited to, shape, size, weight, etc.) of the different computer case designs CASE, graphics processing units GPUs, and related devices and systems. Although the expandable bracket assembly 100 is preferably adjustable along all three axes, the expandable bracket assembly 100 can still carry out some or most of its functions when it is adjustable along any one axis or any two of the three axes.

As a non-limiting embodiment, the expandable bracket assembly 100 preferably comprises a front panel 110, a bracket 130, a bracket extension 150, a GPU support member 180 (with a GPU support member footrest 189), at least one (preferably, a plurality of) front panel-bracket securing element 190, at least one (preferably, a plurality of) bracket-bracket extension securing element 194, at least one (preferably, a plurality of) bracket extension-GPU support member securing element 196, and at least one (preferably, a plurality of) GPU support member securing element 198.

As best shown in FIGS. 1, 2, 8A, 8B, 9A, 9B, 10A, and 10B and as a non-limiting example, the front panel 110 comprises a front side 112, a rear side 114, a left side 116, a right side 118, a front opening or cutout 120, a plurality of openings 122 (preferably, a plurality of honeycomb-shaped openings), a plurality of upper securing openings or holes 124, a plurality of lower securing openings or holes 126, and a plurality of left side securing holes 128. The front opening or cutout 120 is preferably dimensioned and configured for allowing connectors and connecting devices, such as, but not limited to, wires, cords, etc., to pass through the front opening or cutout 120 and connect with the graphics processing unit GPU. The plurality of openings 122 are preferably dimensioned and configured for allowing air and heat to flow through the openings 122 away from the graphics processing unit GPU and into the nearby environment. The plurality of upper securing openings or holes 124 and plurality of lower securing openings or holes 126 are preferably dimensioned and configured for engaging with the corresponding at least one front panel-bracket securing element 190 so that the front panel 110 and bracket 130 may be secured together at a plurality of alternative front panel and bracket securing positions as shown in FIGS. 8A and 8B.

As best shown in FIGS. 1, 5, and 8B and as a non-limiting example, the bracket 130 comprises a front end 132; a rear end 134; a left side 136; a right side 138; a side opening or cutout 140; a top side 142; a bottom side 143; a plurality of upper holes 144; an upper bar 146 (with preferably a plurality of securing holes or openings 147) extending to the right of the upper portion of the front end 132; and a lower bar 148 (with preferably a plurality of securing holes or openings 149) extending to the right of about the lower portion of the front end 132.

As best shown in FIGS. 1, 4, 5, 8A-8B, 9A-9B, and 10A-10B and as a non-limiting example, the bracket extension 150 comprises a front end 152; a rear end 154; a left side 156; a right side 158; a side-bottom opening or cutout 160; a top side 162 (with at least one slot or slit 163); a bottom side 164, and at least one GPU support member receiving hole 166 (which is/are for receiving the at least one GPU support member securing element 198 that detachably secures the GPU support member 180 to the bracket extension 150).

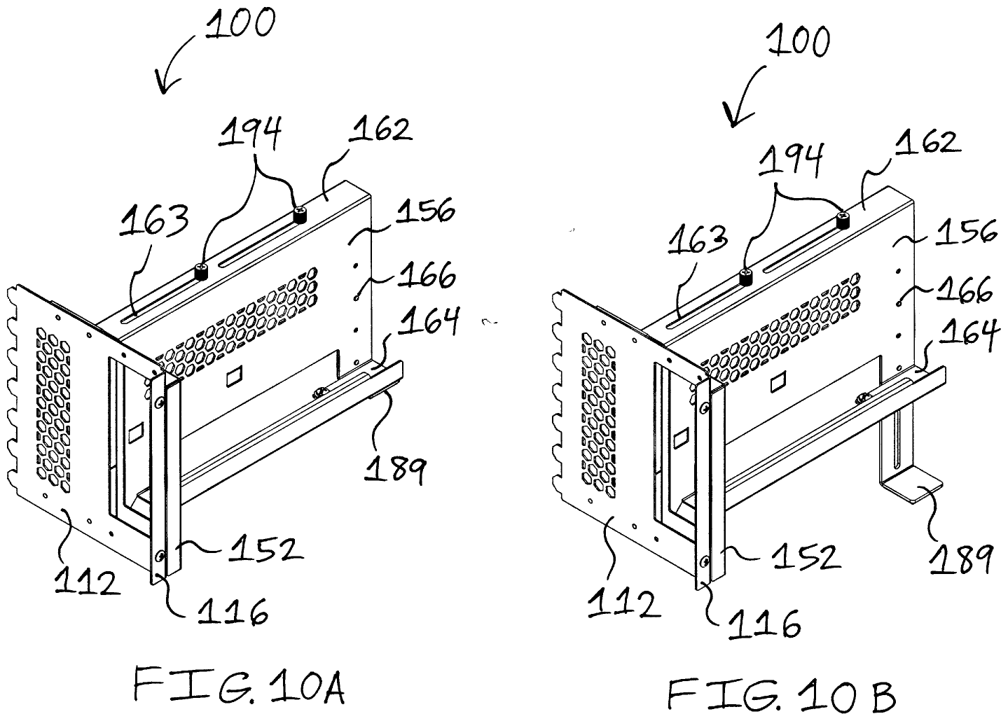

As best shown in FIGS. 1 and 10B and as a non-limiting example, the GPU support member 180 comprises a first end 182, a second end 184, a body 186 extending from the first end 182 to the second end 184, and the GPU support member footrest 189 at or about the second end 184.

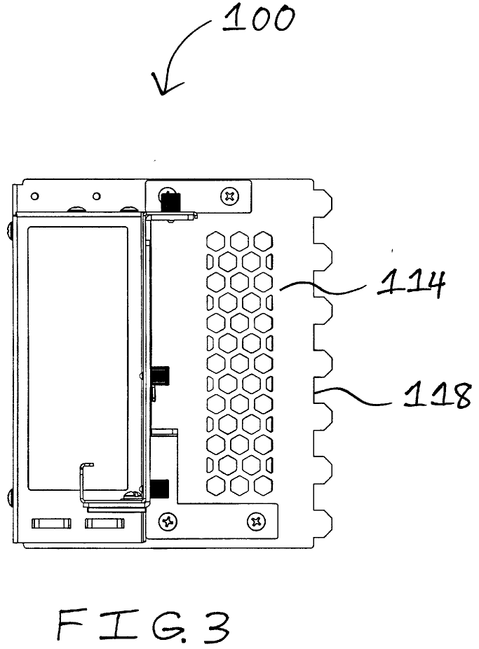

As best shown in FIGS. 1 and 3 and as a non-limiting example, the front panel 110 and bracket 130 are secured to one another at a plurality of securing positions via a plurality of front panel-bracket securing elements 190 being inserted through a plurality of securing holes or openings 147,149 of the bracket 130 and a plurality of upper securing openings or holes 124 and a plurality of lower securing openings or holes 126 of the front panel 110 and

As best shown in FIGS. 8A-8B, 9A-9B, and 10A-10B, the bracket assembly 100 is designed to increase compatibility by incorporating movement and positioning of the parts on preferably three different axes (a front-to-rear axis, a side-to-side axis, and a top-to-bottom axis) to match a variety of computer case designs. The bracket assembly 100 may be placed or positioned in a plurality of positions on or along each of the three different axes.

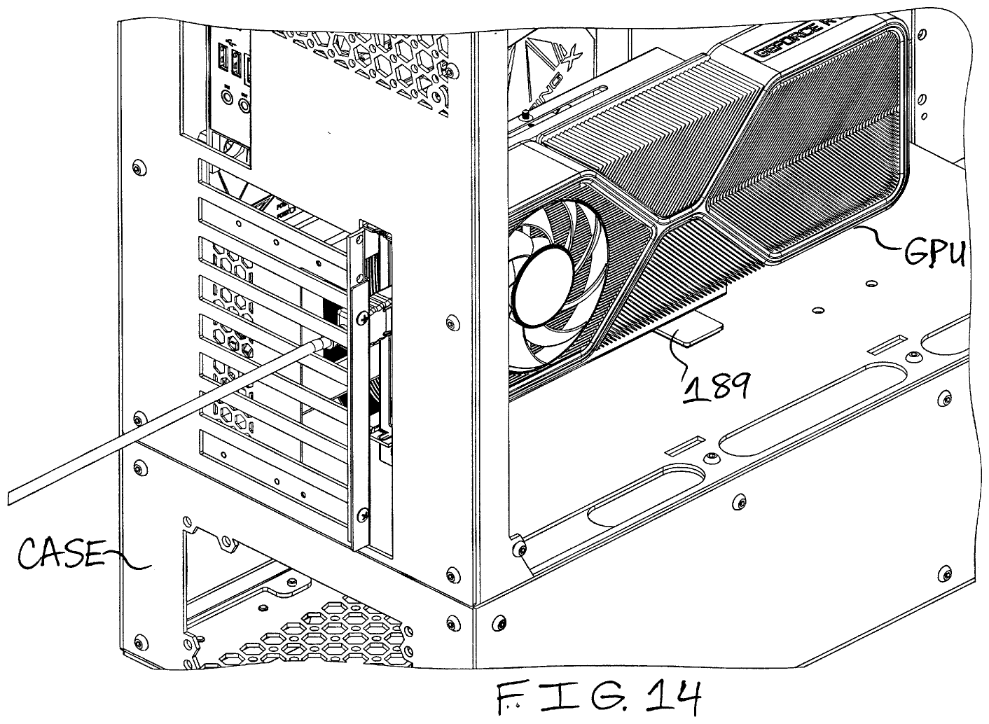

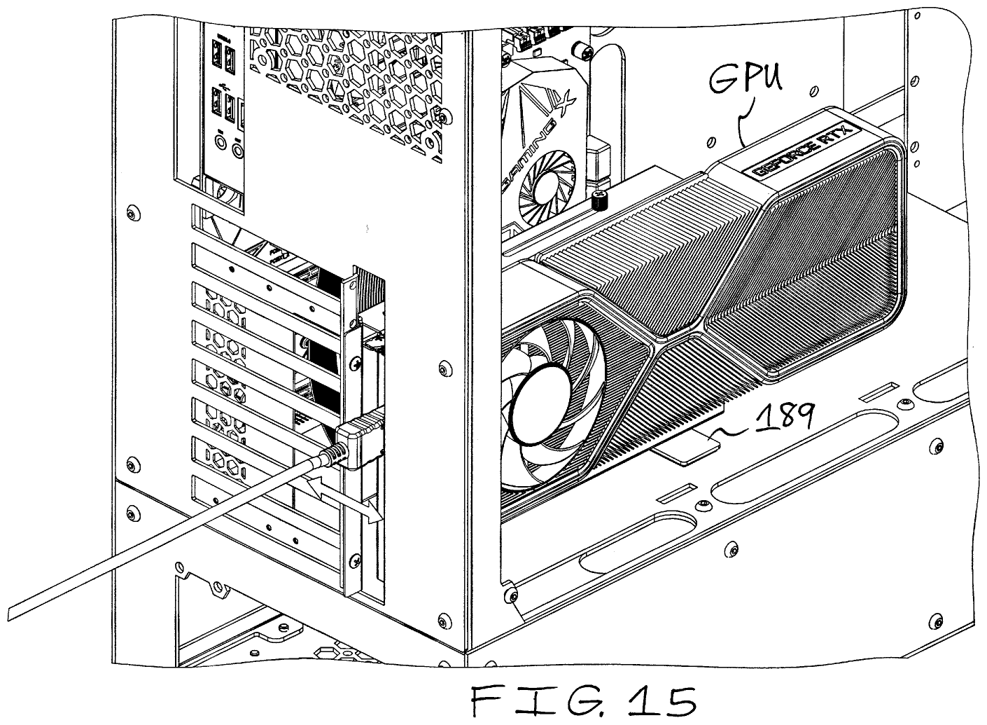

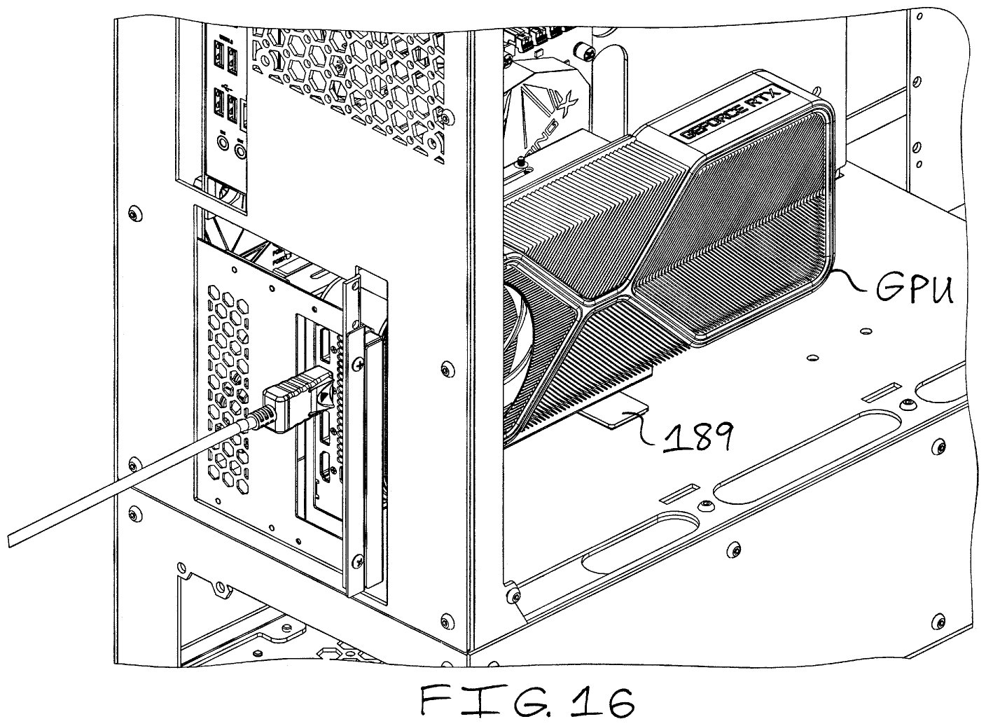

As non-limiting examples, FIGS. 14, 15 and 16 show “Configuration Option 1”, “Configuration Option 2”, and “Configuration Option 3”, respectively, where the GPU 10 (video ports) are accessible despite computer case design limitations. Video cables can be fed through the slot on the side of older cases shown in “Configuration Option 1” (FIG. 14), or the vertical bracket can be moved to the right and the cable can be fed through the holes on the right of some cases seen in “Configuration Option 2” (FIG. 15), or cables can be fed through the larger opening of such cases that have them seen in “Configuration option 3” (FIG. 16). It is not required to use the bracket movement and positioning on the axis in “Configuration option 3” (FIG. 16), and can be used in its base form like a vertical bracket assembly that is not expandable.

As shown in FIGS. 8A-8B, axis one movement allows for pass through the “struts” of the computer case for cable connection, for those that have them.

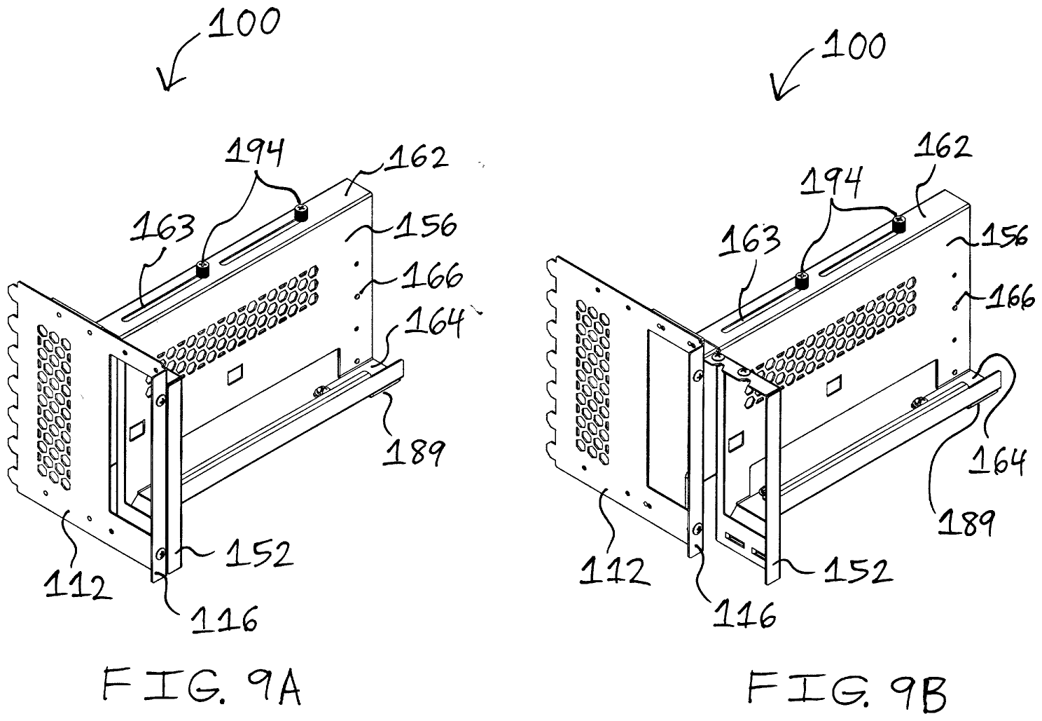

As shown in FIGS. 9A-9B, axis two movement allows for extra compatibility for cable connection/pass through, but also gives more space for routing of the riser cable.

As shown in FIGS. 10A-10B axis three movement gives support for larger GPUs.

FIG. 1 shows an exploded, perspective, front, left side view of an expandable graphics processing unit bracket assembly 100.

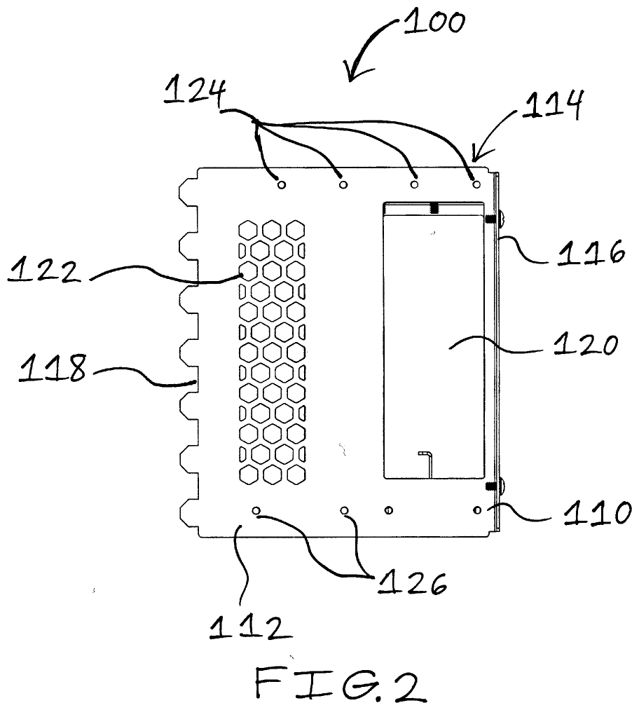

FIG. 2 shows a front view of the expandable graphics processing unit bracket assembly 100.

FIG. 3 shows a rear view of the expandable graphics processing unit bracket assembly 100.

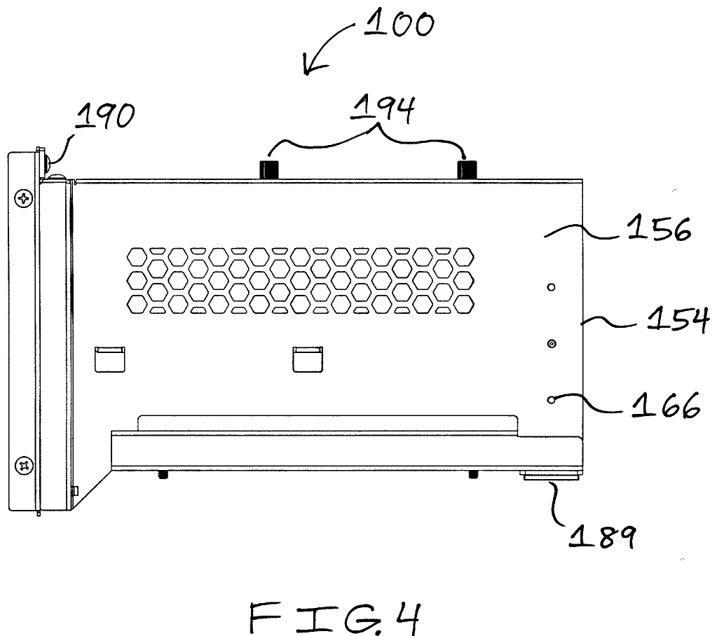

FIG. 4 shows a left side view of the expandable graphics processing unit bracket assembly 100.

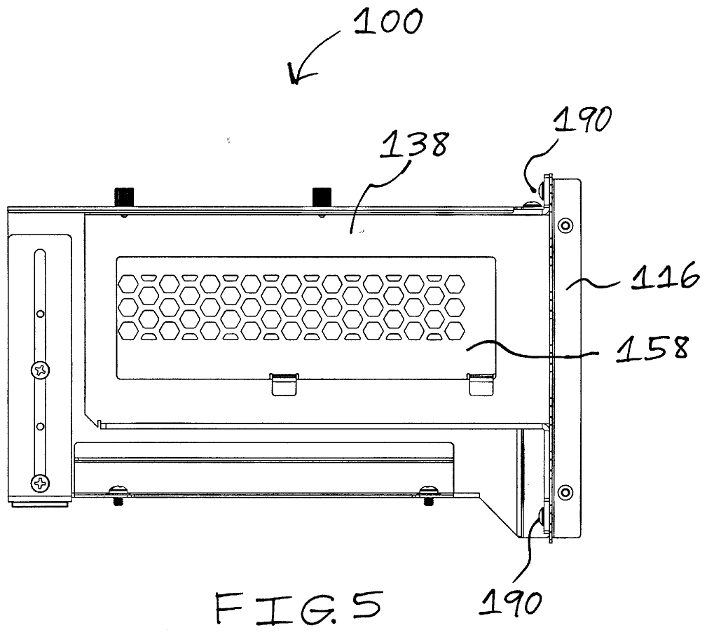

FIG. 5 shows a right side view of the expandable graphics processing unit bracket assembly.

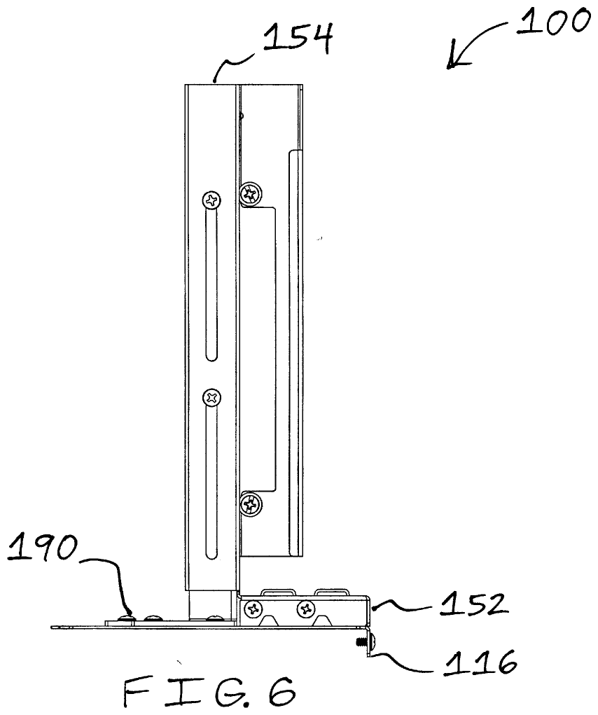

FIG. 6 shows a top view of the expandable graphics processing unit bracket assembly 100.

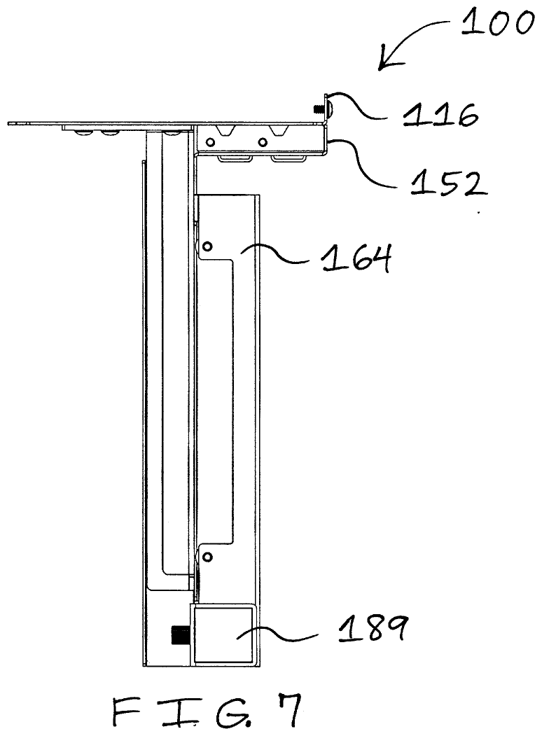

FIG. 7 shows a bottom view of the expandable graphics processing unit bracket assembly 100.

FIGS. 8A and 8B show perspective, front, left side views of the expandable graphics processing unit bracket assembly 100, wherein the bracket assembly 100 is in a first position and a second or another position, respectively, along a front-to-rear axis.

FIGS. 9A and 9B show perspective, front, left side views of the expandable graphics processing unit bracket assembly 100, wherein the bracket assembly is in a first position and a second another position, respectively, along a side-to-side axis.

FIGS. 10A and 10B show perspective, front, left side views of the expandable graphics processing unit bracket assembly 100, wherein the bracket assembly is in a first position and a second another position, respectively, along a top-to-bottom axis.

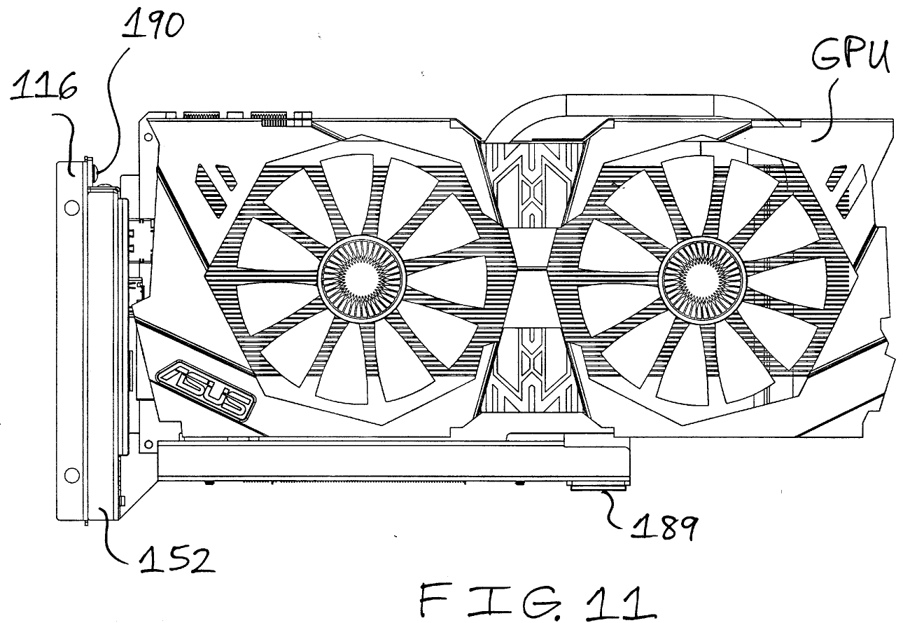

FIG. 11 shows an environmental, left side view of the expandable graphics processing unit bracket assembly 100, wherein a graphics processing unit GPU is retained by the bracket assembly 100.

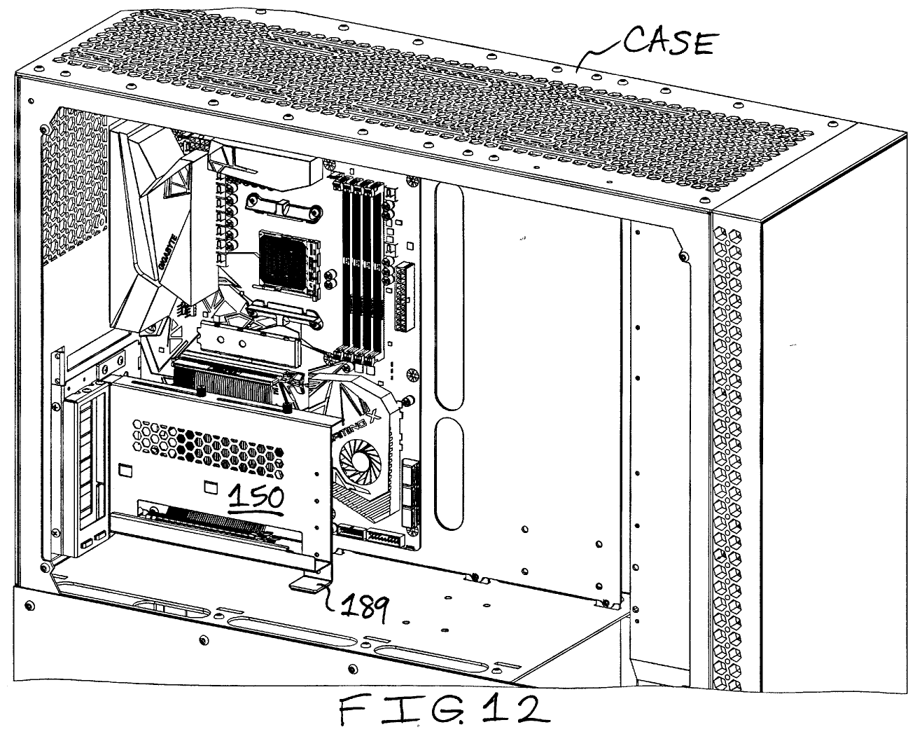

FIG. 12 shows an environmental, perspective, left side view of the expandable graphics processing unit bracket assembly 100, wherein the bracket assembly 100 is secured within a computer case CASE.

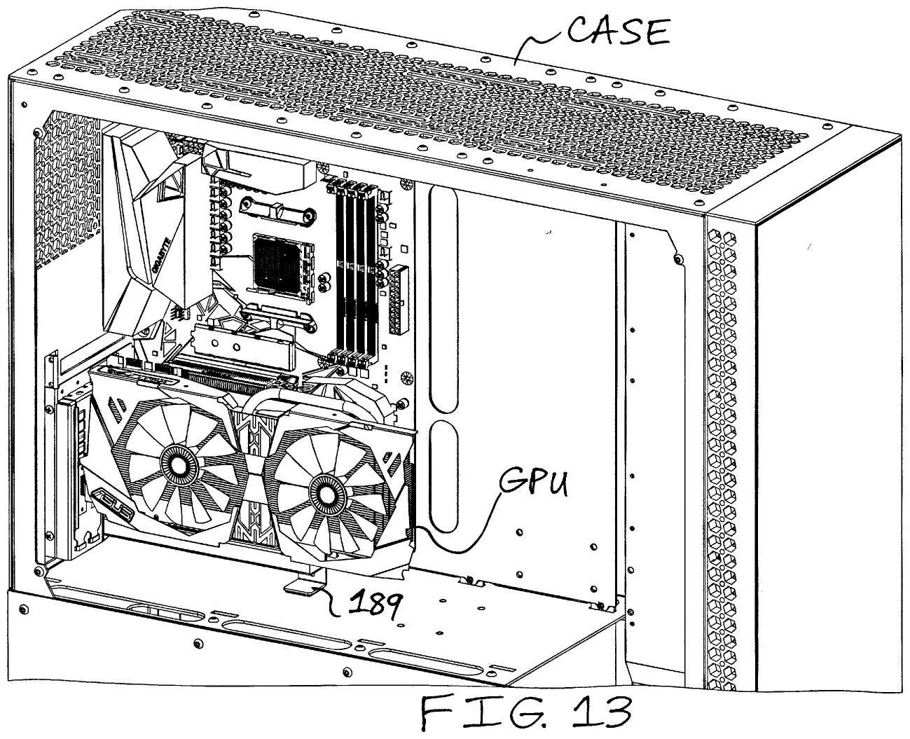

FIG. 13 shows an environmental, perspective, left side view of the expandable graphics processing unit bracket assembly 100, wherein a graphics processing unit GPU is retained by the bracket assembly 100 and secured within a computer case CASE.

FIGS. 14, 15 and 16 show environmental, perspective, front, left side views of the expandable graphics processing unit bracket assembly 100, wherein, in a first configuration, a second configuration, and a third configuration, respectively, a graphics processing unit GPU is retained by the bracket assembly 100 and secured within a computer case CASE.

Preferably, the components (particularly, the front panel 110, the bracket 130, and the bracket extension 150) of the bracket assembly 100 may be made or manufactured of metal, steel, plastic, glass, any material known to one of ordinary skill in the art (OOSIA), and any combination thereof.

It is to be understood that the present invention is not limited to the embodiments described above or as shown in the attached figures, but encompasses any and all embodiments within the spirit of the invention.

1. An expandable graphics processing unit bracket assembly for retaining, securing and/or positioning a graphics processing unit, said expandable bracket assembly comprising:
a front panel;
a bracket;
a bracket extension;
a GPU support member;
at least one front panel-bracket securing element;
at least one bracket-bracket extension securing element;
at least one bracket extension-GPU support member securing element; and
at least one GPU support member securing element,
wherein said expandable bracket assembly is adjustable along at least one axis.

2. The expandable bracket assembly according to claim 1, wherein said expandable bracket assembly is adjustable along a plurality of axes.

3. The expandable bracket assembly according to claim 2, wherein said expandable bracket assembly is adjustable along three axes.
